(19) United States
(12) Patent Application Publication
(10) Pub. No.: US 2008/0174029 A1
(43) Pub. Date: Jul. 24, 2008

(54) SEMICONDUCTOR DEVICE AND METHOD OF FORMING METAL PAD OF SEMICONDUCTOR DEVICE

(75) Inventor: Kyu Cheol SHIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/947,615

(22) Filed: Nov. 29, 2007

(30) Foreign Application Priority Data
Dec. 28, 2006 (KR) 10-2006-0135858

(51) Int. Cl. H01L 23/48; H01L 21/44

(52) U.S. Cl. 257/774; 438/675; 257/E23.01; 257/E21.476

(57) ABSTRACT

A semiconductor device and a method of forming a metal pad of a semiconductor device is provided. The method includes forming a pre-metal dielectric (PMD) layer on a semiconductor substrate and a metal plug through the pre-metal dielectric layer. A metal layer may then be formed on the pre-metal dielectric layer including the metal plug and the metal layer may be selectively etched to form a wiring and a metal pad. Next, a passivation layer may be formed on the PMD layer including the wiring and the metal pad and a photoresist pattern may be formed on the passivation layer. The passivation layer may be selectively removed to expose the metal pad, the photoresist pattern may be removed and a wet cleaning process may be peformed. Then, a radio frequency (RF) sputter etch process may be performed on the semiconductor substrate on which the wet cleaning process has been performed.

### CROSS-REFERENCE TO RELATED APPLICATION

This application claims priority to Korean Application No. 10-2006-0135858, filed on Dec. 28, 2006, which is incorporated herein by reference in its entirety.

### BACKGROUND

1. Field of the Invention

The present invention relates to semiconductor devices and a method of forming a metal pad of the semiconductor device.

2. Background of the Invention

A semiconductor device has several patterns and layers laminated on a wafer, and a plurality of chips may be implemented on a single wafer.

FIGS. 1A to 1E illustrate a method of forming a metal pad of a conventional semiconductor device.

Referring to FIG. 1A, a pre-metal dielectric (PMD) layer 11 is formed on a semiconductor substrate in which a transistor is formed. A tungsten plug 12 is formed through the PMD layer 11.

A metal layer 13 is formed on the PMD layer 11 including the tungsten plug 12 by a physical vapor deposition (PVD) method.

Referring to FIG. 1B, a photoresist pattern is formed on the metal layer 13. The metal layer 13 is then selectively etched through photolithography and etch processes, so that a wiring 13b and a metal pad 13a are formed.

Referring to FIG. 1C, a passivation layer 14 is formed on the PMD layer 11 including the wiring 13b and the metal pad 13a. The passivation layer 14 can be formed from phosphosilicate glass (PSG) or undoped silicate glass (USG) by a chemical vapor deposition (CVD) method. A metal sintering process is then performed by using a furnace.

After that, a photoresist 15 is coated on the passivation layer 14.

Referring to FIG. 1D, the photoresist 15 is patterned to form a photoresist pattern 15a. The passivation layer 14 is selectively removed by using the photoresist pattern 15a as a mask so that the metal pad 13a is exposed.

Referring to FIG. 1E, the photoresist pattern 15a is removed and a wet cleaning process is then performed.

After the wet cleaning process, a final cure and a process control monitoring (PCM) process for checking electrical characteristics of the device are carried out.

However, in the conventional metal pad formation method, at the time of wire bonding for packaging, the metal pad may be contaminated or corroded in a cleaning process or a thin TiN layer may not be removed completely. Accordingly, contaminants 18 are formed and failure occurs in a wire bonding process.

Further, in the metal pad formation process, if a Ti/Al/Ti/TiN process is carried out, TiAl3 is formed due to thermal budget or the like in subsequent processes, such as a passivation layer formation process and a sintering process. TiAl3 has a detrimental effect, however, on bonding of the metal pad.

### SUMMARY OF SOME EXAMPLE EMBODIMENTS

In general, example embodiments of the invention relate to a semiconductor device and a method of forming a metal pad of a semiconductor device, in which a cleaning process can be performed effectively in a metal pad formation process.

In accordance with one example embodiment, there is provided a method of forming a metal pad of a semiconductor device including forming a pre-metal dielectric (PMD) layer on a semiconductor substrate and a metal plug through the pre-metal dielectric layer. Next, a metal layer may be formed on the pre-metal dielectric layer including the metal plug and selectively etching the metal layer to form a wiring and a metal pad. A passivation layer may then be formed on the PMD layer including the wiring and the metal pad and a photoresist pattern may be formed on the passivation layer and selectively removed to expose the metal pad. Once the metal pad is exposed, the photoresist pattern may be removed and a wet cleaning process may be performed. Finally, a radio frequency (RF) sputter etch process may be performed on the semiconductor substrate on which the wet cleaning process has been performed.

In accordance with another example embodiment, a semiconductor device may include a PMD layer disposed on a semiconductor substrate, the PMD layer having a metal plug disposed therein. A wiring and a metal pad may be disposed on the PMD layer and a passivation layer may be selectively disposed on the PMD layer to expose the metal pad. A level of contaminants on the passivation layer and the metal pad may be reduced by a wet cleaning process and a radio frequency (RF) sputter etch process performed on the semiconductor substrate.

### BRIEF DESCRIPTION OF THE DRAWINGS

Aspects of example embodiments of the invention will become apparent from the following description of example embodiments given in conjunction with the accompanying drawings, in which:

FIGS. 1A to 1E illustrate a method of forming a metal pad of a conventional semiconductor device; and

FIGS. 2A to 2E illustrate a semiconductor device in accordance with the present invention and a method of forming a metal pad of the semiconductor device in accordance with the present invention.

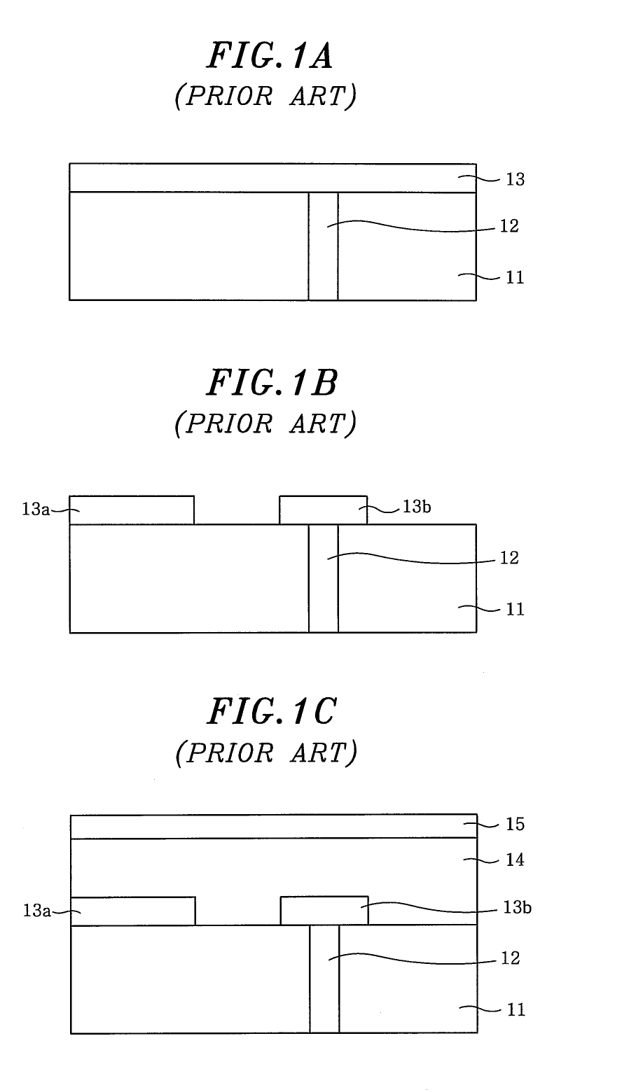

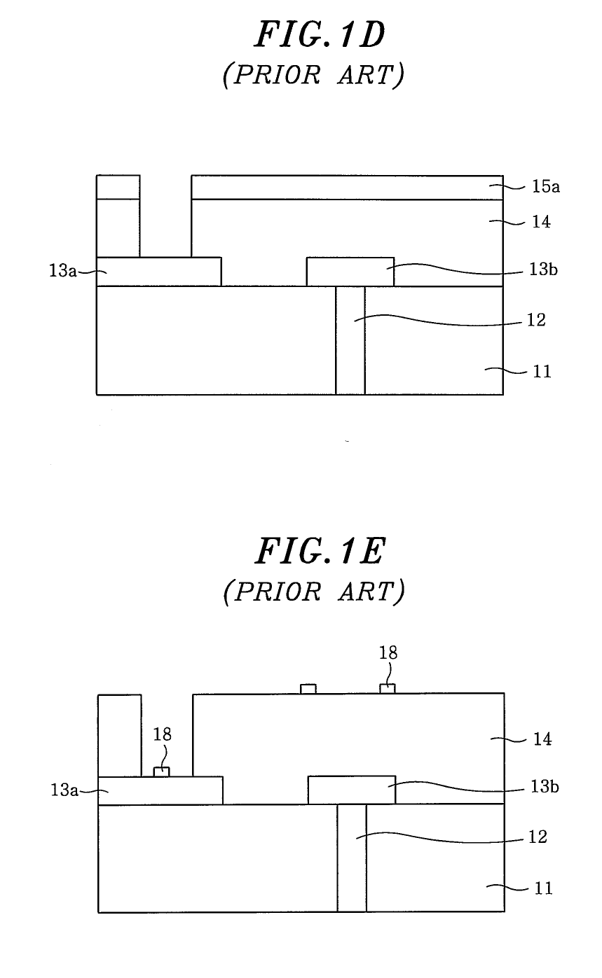

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

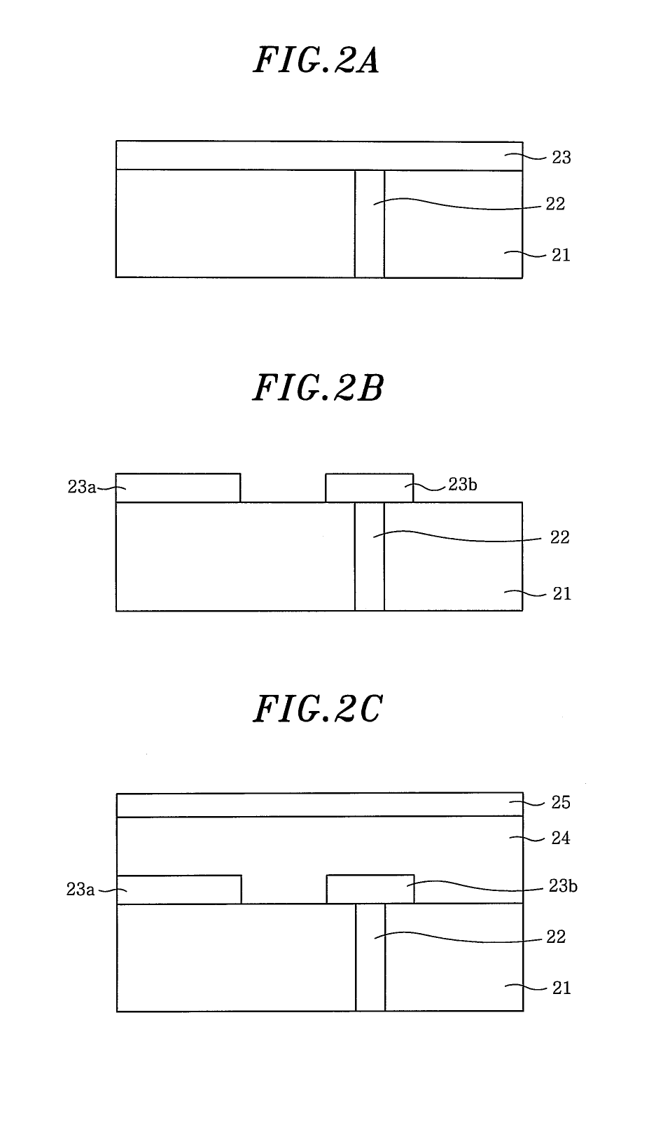

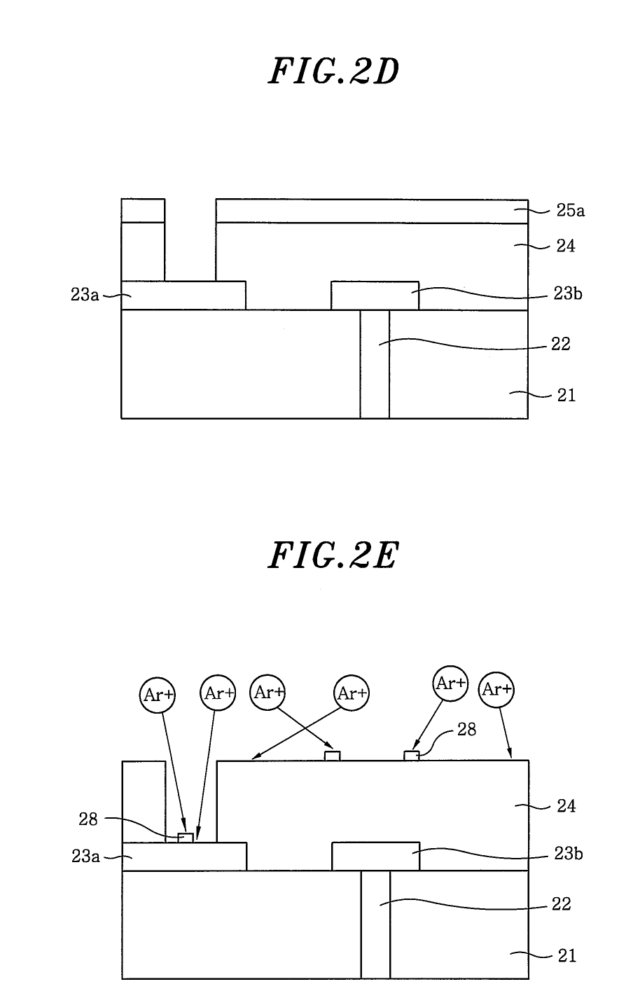

FIGS. 2A to 2E illustrate a semiconductor device and a method of forming a metal pad of the semiconductor device in accordance with an example embodiment.

Referring to FIG. 2A, a PMD layer 21 may be formed on a semiconductor substrate in which a transistor is formed. A tungsten plug 22 may be formed through the PMD layer 21.

A metal layer 23 may be formed on the PMD layer 21 including the tungsten plug 22 by a PVD method.

Referring to FIG. 2B, a photoresist pattern may be formed on the metal layer 23. The metal layer 23 may then be selectively etched through photolithography and etch processes, thus forming a wiring 23b and a metal pad 23a.

Referring to FIG. 2C, a passivation layer 24 may be formed on the PMD layer 21 including the wiring 23b and the metal pad 23a. The passivation layer 24 can be formed from one of PSG, USG and SiN by a CVD method. A metal sintering process may then be carried out by using a furnace.

After that, a photoresist 25 may be coated on the passivation layer 24.

Referring to FIG. 2D, the photoresist 25 may be patterned to form a photoresist pattern 25a. The passivation layer 24 may be selectively removed by using the photoresist pattern 25a as a mask, so that the metal pad 23a is exposed.

Referring to FIG. 2E, the photoresist pattern 25a may be removed and a wet cleaning process may then be performed.

Even after the wet cleaning process, contaminants 28, such as polymer, TiAl3 and corrosion, may remain on the metal pad 23a and the passivation layer 24.

Thus, according to an example embodiment, the contaminants 28 may be removed by an RF sputter etch process.

The RF sputter etch process can employ a plasma source method, such as an inductively coupled plasma (ICP) source method and/or a capacitively coupled plasma (CCP) source method.

Further, the RF sputter etch process may be performed by using Ar or Ar gas containing H2, and a pressure of the gas may be in a range from about 0.5 mTorr to about 10 mTorr.

In order to reduce plasma damage, the RF sputter etch process may be performed by using a self-DC bias power in a range from about −50 V to about 500V.

After the RF sputter etch process, a final cure and a PCM process for checking electrical characteristics of the device may be carried out.

As described above, in an example embodiment of a metal pad formation process, a cleaning process is performed effectively. Accordingly, wire-bonding characteristics can be improved.

While the invention has been shown and described with respect to the embodiments, it will be understood by those skilled in the art that various changes and modifications may be made without departing from the scope of the invention as defined in the following claims.

What is claimed is:

1. A method of forming a metal pad of a semiconductor device, comprising:
forming a pre-metal dielectric (PMD) layer on a semiconductor substrate and a metal plug through the pre-metal dielectric layer;
forming a metal layer on the pre-metal dielectric layer including the metal plug and selectively etching the metal layer to form a wiring and a metal pad;
forming a passivation layer on the PMD layer including the wiring and the metal pad;
forming a photoresist pattern on the passivation layer and selectively removing the passivation layer to expose the metal pad;
removing the photoresist pattern and performing a wet cleaning process; and
performing a radio frequency (RF) sputter etch process on the semiconductor substrate on which the wet cleaning process has been performed.

2. The method of claim 1, wherein the passivation layer is formed from one of phosphosilicate glass (PSG), undoped silicate glass (USG), and SiN by a chemical vapor deposition (CVD) method.

3. The method of claim 1, wherein the radio frequency sputter etch process employs at least one of an inductively coupled plasma (ICP) source method and a capacitively coupled plasma (CCP) source method.

4. The method of claim 1, wherein the radio frequency sputter etch process is performed by using Ar or Ar gas containing H₂.

5. The method of claim 4, wherein a pressure of the Ar gas or the Ar gas containing H₂ is in a range from about 0.5 mTorr to about 10 mTorr.

6. The method of claim 1, wherein the radio frequency sputter etch process is performed by using a self-DC bias power in a range from about −50 V to about 500 V.

7. A semiconductor device made by the process of claim 1.

8. A semiconductor device comprising:
a semiconductor substrate;
a PMD layer disposed on the semiconductor substrate, the PMD layer having a metal plug disposed therein;
a wiring and a metal pad disposed on the PMD layer, at least a portion of a top surface of the wiring and the metal pad having a sputter etched layer;
a passivation layer disposed on the PMD layer so as to substantially expose the metal pad; and
wherein a level of contaminants on the passivation layer and the metal pad is reduced by a wet cleaning process and a radio frequency (RF) sputter etch process performed on the semiconductor substrate.

9. The device of claim 8, wherein the passivation layer is formed from one of PSG, USG, and SiN by a CVD method.

10. The device of claim 8, wherein the sputter etched layer is provided via a radio frequency sputter etch process employing at least one of an ICP source method and a CCP source method.

11. The device of claim 8, wherein the sputter etched layer is provided by a radio frequency sputter etch process using Ar or Ar gas containing H₂.

12. The device of claim 11, wherein a pressure of the Ar gas or the Ar gas containing H₂ is in a range from about 0.5 mTorr to about 10 mTorr.

13. The device of claim 7, wherein the sputter etched layer is provided by a radio frequency sputter etch process using a self-DC bias power in a range from about −50 V to about 500 V.
